(19) United States
(12) Patent Application Publication
(10) Pub. No.: US 2006/0197008 A1
(43) Pub. Date: Sep. 7, 2006

(54) Light-receiving device having an optical fuse

(76) Inventors: Takatoshi Kato, Yokohama-shi (JP); Katsumi Uesaka, Yokohama-shi (JP)

Correspondence Address: FISH & RICHARDSON P.C., P.O. BOX 1022, MINNEAPOLIS, MN, 55440-1022, US

(21) Appl. No.: 11/354,542

(22) Filed: Feb. 14, 2006

Related U.S. Application Data
(60) Provisional application No. 60/659,753, filed on Mar. 7, 2005.

(30) Foreign Application Priority Data
Feb. 15, 2005 (JP) 2005-038067

(51) Int. Cl. H01J 40/14; H01L 31/00; H03K 17/78

(52) U.S. Cl. 250/214.1; 250/214 R; 250/214 SW; 250/227.11

(57) ABSTRACT

The present invention provides a light-receiving device that may escape the device from the breakdown thereof and may suppress an optical loss. The light-receiving device of the invention includes a surface to sense the light and a thin film made of PbSe nano-particles, diameters of which are smaller than 20 nm. This thin film operates as an optical fuse, so the device may be escaped from the breakdown thereof. Moreover, the thin film is disposed directly onto the light-sensing surface of the device, the optical loss cause between the thin film and the sensing surface may be suppressed.

### REFERENCE TO PRIORITY APPLICATION

This application claims priority to U.S. Provisional Application Ser. No. 60/659,753, filed Mar. 11, 2005.

### BACKGROUND OF THE INVENTION

1. Field of the Invention

The present invention relates to a light-receiving device such as photodiode and planar optical waveguide.

2. Related Prior Arts

Recently, an optical source with high power can be available by using an erbium-doped optical amplifier. However, when a short optical pulse enters the optical amplifier as it is set to a high gain, an extremely high optical power is instantaneously output from the optical amplifier. This may damage various optical parts arranged in the output of the optical amplifier, in particular, which may break parts having less tolerance to the optical power such as avalanche photodiode. In other cases, when the light-receiving device is replaced as the optical signal is input therein or the optical output with a high average power is emitted therefrom, an optical pulse with high power may be generated just after installing the light-receiving device and this optical pulse may enter the light-receiving device, thereby breaking the device.

Various approaches have been investigated to escape the light with high power from entering the light-receiving device. One method is to use an optical fuse. The optical fuses, which prohibit the transmission of light with magnitude thereof exceeding a threshold, have been disclosed as a semiconductor device with an optical waveguide structure in Japanese patents published as JP-H09-146056A and JP-H09-297826A. These optical fuses prohibit the light transmission by utilizing an optical damage generated in an end facet of the optical waveguide.

Another Japanese patent published as JP-2004-046084 has disclosed an optical fuse made of carbon nano-tube formed in the optical fiber. Materials that reduce the light transmittance as increasing a temperature thereof, and dielectric material made of metal compound have been suggested to apply to the optical fuse in Japanese patents published as JP-H11-282142A and JP-2002-221740A, respectively. Still further, an optical film with decreasing the light transmittance thereof as increasing the optical power has been disclosed in Japanese patent published as JP-H11-274547A.

These optical fuses mentioned above, although having advantages in respect of protecting the light-receiving device from optical damage, must be placed to be optically coupled with the light-receiving device as facing the light-sensing surface thereof, thereby increasing the optical loss. For instance, the optical fuse having a type of the optical waveguide mentioned above, the optical coupling between the optical fiber requires a skill, generally causing an optical coupling loss of a few decibels at least. Other fuses inevitably bring the optical loss for the light-receiving device to be protected.

Therefore, one of subjects of the present invention is to provide a light-receiving device that protects a self breaking by the light with an excessive magnitude as suppressing the optical loss of the light to be detected thereby.

### SUMMARY OF THE INVENTION

A light-receiving device of the present invention provides a light-sensing surface and a thin film containing nano-particles, which are made of PbSe and have a diameter less than 20 nm. The light-receiving device of the present invention includes not only optical detectors such as photo detector but also optical fibers and optical waveguides such as planar light-wave circuit (PLC).

Since the thin film mentioned above functions as an optical fuse, the light-receiving device may protect itself from breaking by light with an excessive magnitude. The thin film is deposited in direct onto a light-sensing surface of the light-receiving device, without another optical part to optically couple the thin film the light-sensing surface, optical loss may be reduced.

When the light with magnitude thereof exceeding a first threshold enters the thin film, the transmittance of the film may decrease for light having a predetermined wavelength. The thin film may break when light with magnitude thereof exceeding a second threshold, which is greater than the first threshold.

The light-receiving device of the present invention comprises a first semiconductor layer with first conduction type, a multiplication layer disposed on the first semiconductor layer, a second semiconductor layer with a second conduction type disposed on the multiplication layer, and first and second electrodes. The first electrode is electrically connected with the first semiconductor layer, while the second electrode is electrically connected with the second semiconductor layer. The light-sensing surface may be provided on the second semiconductor layer. Further, the second electrode may be disposed onto the second semiconductor layer and have a ring-shaped configuration. The thin film of the present invention may be disposed within the ring of the second electrode. Thus configured light-receiving device may provide a small sized device and function as an avalanche photodiode.

### BRIEF DESCRIPTION OF DRAWINGS

FIG. 1 is a schematic diagram showing a light-receiving device according to the first embodiment of the invention;

FIG. 2 shows an end surface of the light-receiving device shown in FIG. 1;

FIG. 3 shows an optical response of the thin film provided in the light-receiving device;

FIG. 4 is a plan view showing an optical system, by which the optical response shown in FIG. 3 is measured; and

FIG. 5 is a perspective view showing a second embodiment of the present invention.

### DETAILED DESCRIPTION OF THE INVENTION

Next, preferred embodiments of the present invention will be described as referring to accompanying drawings. In the specification and drawings, same elements will be referred by same symbols and numerals without overlapping explanations.

### First Embodiment

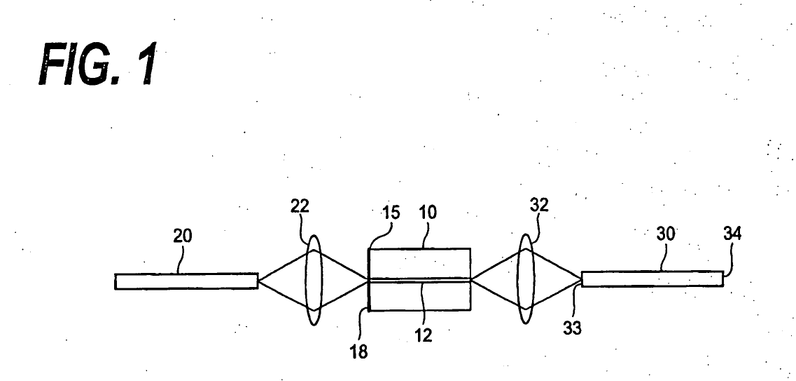

FIG. 1 is a schematic diagram shown a light-receiving device of the present invention. The light-receiving device 10 has a configuration of a planar light-wave circuit (PLC) including a core 12. In FIG. 1, two, optical fibers 20 and 30, and two focusing lenses 22 and 32 are illustrated. The former optical fiber and the lens, 20 and 22, respectively, are to enter light into the light-receiving device 10, while the latter optical fiber and lens, 30 and 32, respectively, are to guide light output from the light-receiving device 10. Two optical fibers 20 and 30 are designed to propagate light with a predetermined wavelength. In the present embodiment, to the second fiber 30 via the light-receiving device 10.

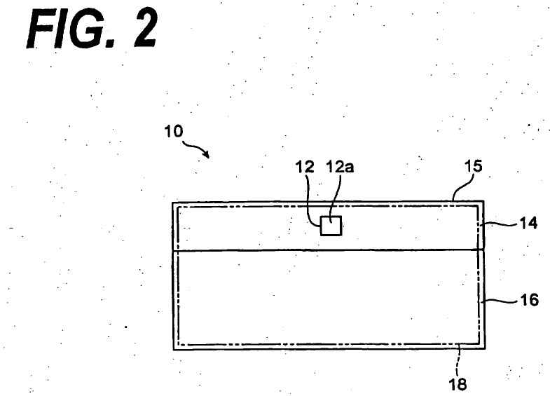

FIG. 2 shows one of end surfaces of the light-receiving device 10. The end surface 15 functions as a light-sensing surface. The core 12 is surrounded by a cladding layer 14 having a refractive index smaller than that of the core 12, and the cladding layer 14 is disposed on a substrate 16. An edge 12a of the core 12 exposed in the end surface 15 is optically coupled with the optical fiber 20 via the focusing lens 22. The light emitted from the fiber 20, concentrated by the focusing lens 22, optically couples with the core 12 with enough coupling efficiency. The light, thus enters the core 12 and propagates therein, emits from the other edge opposite to the incident edge 12a, concentrated by the focusing lens 32 and optically couples with the other fiber 32 with enough optical coupling efficiency. Thus, the light emitted from the optical fiber 20 may be coupled with the other fiber 30 via the light-receiving device 10.

The end surface 15 is coated with a thin film 18 comprised of silica (silicon die-oxide: SiO₂) doped with nano-particles made of PbSe. The doping concentration of the PbSe nano-particle is about 22 mg/ml, and a thickness of the film is about 50 μm.

The thin film 18 may be formed by sequential steps of, (1) the silica sol doped with the PbSe nano-particle is spin-coated on the end surface 15 of the light-receiving device 10, and (2) curing thus coated silica sol by the heat treatment. Another method is that a thin film 18 formed in advance is attached onto the end surface 15 with an adhesive.

As shown in later of this specification, the thin film 18 has a characteristic that the transmittance thereof for the wavelength relating to the design of the optical fiber, decreases when it receives light with an optical power exceeding a fist magnitude. Accordingly, the thin film 18 operates as an optical fuse to protect the light-receiving device 10 from the light with the excessive magnitude. This optical property of the thin film is derived from the PbSe nano-particle having diameters small enough. The diameter of the PbSe nano-particle may be smaller than 20 nm to exhibit the function of the optical fuse. In the present embodiment, the diameter of the PbSe nano-particle is around 10 nm.

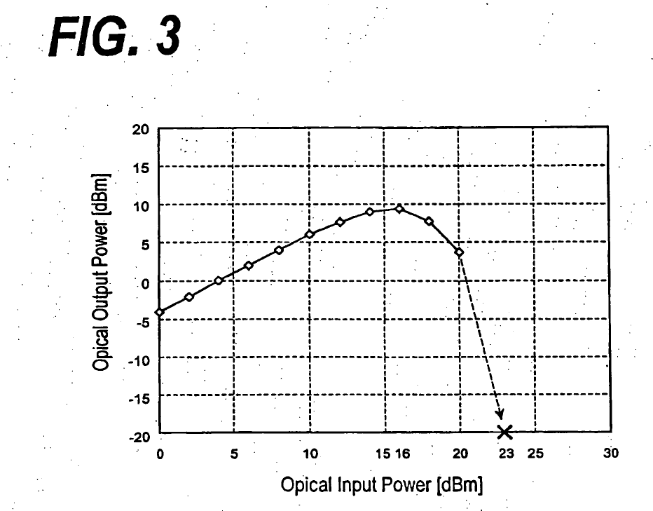

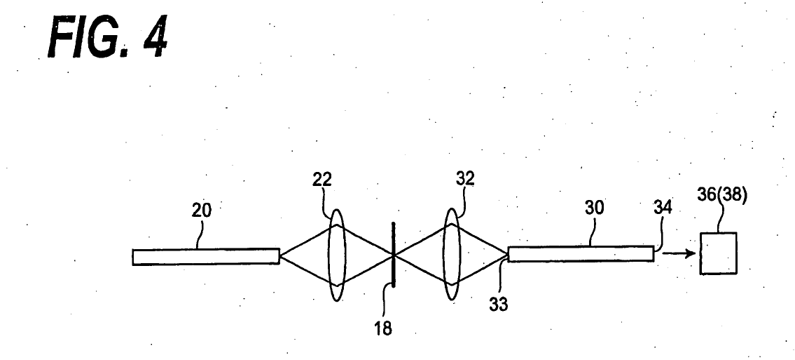

Next, an optical response of the thin film 18 will be explained as referring to FIG. 3 and FIG. 4. FIG. 3 shows an optical response of the thin film 18, while FIG. 4 is a schematic diagram used for measuring the optical response, shown in FIG. 3, of the thin film 18. As shown in FIG. 4, the thin film 19 optically couples in front surface thereof with the optical fiber 20 via the focusing lens 22. The back surface of the thin film 18 optically couples with the tip 32 of the optical fiber 30 via another focusing lens 32, and the other tip 34 of the fiber 30 couples with an optical detector 36. The output optical power, corresponding to the vertical axis in FIG. 3, is measured by this optical detector 36.

As shown in FIG. 3, the difference between the input optical power and the output optical power is kept constant in a region where the input optical power is less than +10 dBm, which means that the thin film 18 causes constant optical loss. However, when the input optical power exceeds +10 dBm, the difference between the input and output optical powers increases, which means the optical loss caused by the thin film 18 increases as the optical input power increases. Further, in the range of the input optical power over +16 dBm, the output optical power decreases in spite of the increasing of the input optical power. Finally, the output optical power becomes zero at the input optical power of +23 dBm, which means that the thin film 18 breaks by receiving the light with an optical power thereof over +23 dBm and the transmittance thereof becomes zero. Since the thin film 18 has the optical properties thus explained, it may protect the light-receiving device from the light with excessive power when placed in front of the device.

In the following explanation, an optical component 38 is assumed to be placed instead of the optical detector 36 in FIG. 3, and this optical component 38 will break when it receives the light with an optical power over +10 dBm. First, to compare the thin film 18 of the present invention, assuming the case that another optical film, which causes constant optical loss of 5 dB, is placed in front of the optical component 38. In this configuration, the optical component 38 would break when the light with magnitude thereof over +15 dBm enters the thin film, because the magnitude of the light transmitting through the thin film and enters the optical component becomes over +10 dBm.

On the other hand, as shown in FIG. 4, the present thin film 19 increases the optical loss thereof when the input optical power exceeds +10 dBm, accordingly, the optical power output from the thin film 18 may be controlled below +10 dBm. Thus, the optical component 38 disposed in the output side of the light-receiving device 10 only receives the light with magnitude below +10 dBm, thereby definitely protecting the optical component 38 from breaking. Since the thin film 18 breaks at the input optical power of +23 dBm, the margin from exhibiting the function of the optical fuse, +15 dBm in the input optical power, to the breakdown thereof at the +23 dBm increases to 8 dB, which is compared to the case that the thin film has not the property of the optical fuse.

Such thin film 18 covers the light-sensing surface 15 of the light-receiving device 10, and exhibits the property of the optical fuse. Accordingly, the light-receiving device may be protected from the breakdown due to the light with excessive optical power. Further, since the thin film 18 is deposited directly onto the light-sensing surface of the light-receiving device, the optical loss occurred therebetween can be reduced.

### Second Embodiment

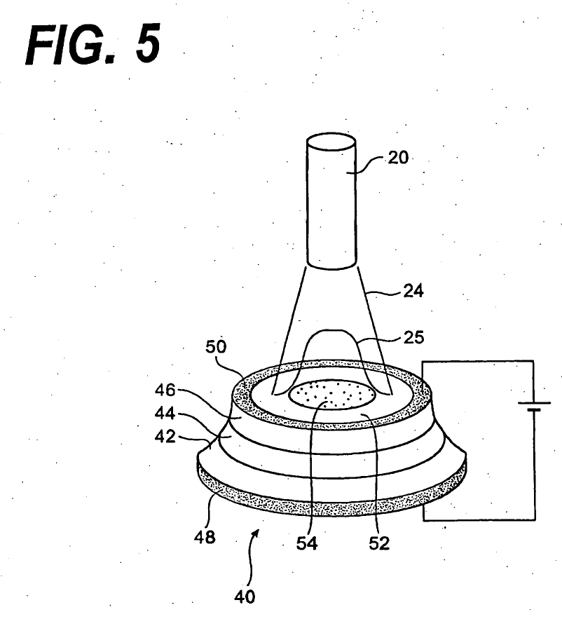

FIG. 5 is a perspective view showing the light-receiving device according to the second embodiment of the invention. The light-receiving device 40 is an avalanche photodiode (APD) and includes a p-type semiconductor layer 42, a multiplication layer 44, and an n-type semiconductor layer 46, sequentially stacked in this order. Below the p-type layer 42 is provided with a first electrode 48, while onto the n-type layer 46 is provided with a second electrode 50. In this embodiment, the second electrode 50 is a ring-shaped and arranged in edges of the n-type layer 46. A portion of the n-type layer 46 surrounded by the ring-shaped second electrode 50 operates as a light-sensing surface 52. In FIG. 5, an optical fiber for guiding the light to the light-sensing surface 52 is also illustrated.

Biasing the p-type layer 42 and the n-type layer via the first and second electrodes with an enough reverse voltage, the light-receiving device 46 operates as the avalanche photodiode. That is, the light-receiving device 40 receives light emitted from the optical fiber 20 and entering the light-sensing surface 52, converts light thus entering the light-receiving device into carriers, and multiplies carriers in the multiplication layer 44.

On a center portion of the light-sensing surface 52 is formed with a thin film 54 having a circular and a planar shape. The thin film 54 has a composition and a thickness substantially equal to those of the thin film 18 of the first embodiment, accordingly exhibits the function of the optical fuse to protect the light-receiving device 40 from the light with the excessive optical power. The thin film 54 is deposited onto the light-sensing surface, which is also similar to those shown in the first embodiment, so the optical loss may be reduced. Further, the second electrode 50 is formed on the same surface where the thin film 54 is deposited, which enables the light-receiving device to miniaturize.

As shown in FIG. 5, the thin film 54 is not necessary to cover the whole of the light-sensing surface. The light emitted from the optical fiber 20 has a field pattern as shown in FIG. 5. On the other hand, the breakdown of the light-receiving device 40 depends on the optical power (an optical power divided by an area), namely depends on the optical power density, and is likely to occur at the portion where the optical power density becomes a maximum. Therefore, only the area where the optical power density is large is covered by the thin film 54, not coating the whole of the light-sensing surface, it is able to reduce the peak optical power as maintaining the total or integrated optical power. These arrangements of the thin film 54 is quite effective for light-receiving device, the output of which is determined by the total optical power, not depending on the geometrical distribution of the optical input power, such as avalanche photodiode.

Thus, the invention is described as referring to accompany drawings. However, the present invention is not restricted to those embodiments shown in drawings and explanations, and may be modified in various within a scope thereof.

For examples, the base material, into which PbSe nano-particles are dopes, is not restricted to silica as long as it may dope PbSe nano-particle with maintaining properties thereof as the nano-particle and may coat the light-sensing surface. One example for the substitution for the base material is poly-methyl-methacrylate (PMMA).

Moreover, the spirit of the present invention may be applicable, not restricted to the planar light-wave circuit and the avalanche photodiode, to the optical fiber and other light-receiving device.

What is claimed is:

1. A light-receiving device, comprising:
a light-sensing surface; and
a thin film formed onto the light-sensing surface and having a transmittance at a predetermined wavelength,
wherein the thin film is made of PbSe nano-particles whose diameters are smaller than 20 nm.

2. The light-receiving device according to claim 1,
wherein the transmittance of the thin film decreases when the thin film receives light with an optical power greater than a first preset value.

3. The light-receiving device according to claim 2,
wherein the thin film breaks when the thin film receives light with an optical power greater than a second preset value.

4. The light-receiving device according to claim 1, further comprises
a first semiconductor layer with a first conduction type,
a multiplication layer formed onto the first semiconductor layer,
a second semiconductor layer formed onto the multiplication layer and having a second conduction type different from the first conduction type,
a first electrode electrically connected to the first semiconductor layer, and
a second electrode electrically connected to the second semiconductor layer,
wherein the light-sensing surface is formed on the second semiconductor layer and the light-receiving device operates as an avalanche photo diode.

5. The light-receiving device according to claim 4,
the second electrode has a ring shape formed on the second semiconductor layer, and the thin film is formed within the ring of the second electrode.
